(19) United States
(12) Patent Application Publication
(10) Pub. No.: US 2012/0057439 A1
(43) Pub. Date: Mar. 8, 2012

(54) Photovoltaic panel, wristwatch, and method of manufacturing photovoltaic panel

(76) Inventors: Hiroshi Shimizu, Chiba-shi (JP); Akira Takakura, Chiba-shi (JP); Kazumi Sakumoto, Chiba-shi (JP); Kenji Ogasawara, Chiba-shi (JP); Keishi Honmura, Chiba-shi (JP); Saburo Manaka, Chiba-shi (JP); Kosuke Yamamoto, Chiba-shi (JP)

(21) Appl. No.: 13/199,493

(22) Filed: Aug. 31, 2011

(30) Foreign Application Priority Data
Sep. 2, 2010 (JP) 2010-197008
Jul. 1, 2011 (JP) 2011-147385

(51) Int. Cl. G04G 19/00; H01L 31/02; H01L 31/05

(52) U.S. Cl. 368/205; 136/244; 438/80; 438/73; 438/14; 257/E31.113

(57) ABSTRACT

Provided is a photovoltaic panel in which a plurality of photovoltaic cells is electrically connected in series, and in which at least one of the photovoltaic cells is set as a non-use cell which is not electrically connected to the other photovoltaic cells and not used.

### BACKGROUND OF THE INVENTION

1. Field of the Invention

The present invention relates to a photovoltaic panel, a wristwatch, and a method of manufacturing the photovoltaic panel.

2. Background Art

In recent years, photovoltaic cells are widely and commonly used from the perspective of the efficient use of energy. Among photovoltaic cells, a photovoltaic cell using an amorphous silicon thin film which can be manufactured at a lower cost has been used widely.

FIG. 9 is a schematic cross-sectional view showing an example of an amorphous silicon photovoltaic cell.

As shown in the figure, an amorphous silicon photovoltaic cell 700 has a laminated structure 705 in which a first electrode layer 702, such as TCO, is formed on a glass substrate 701 as a lower electrode, and an electricity generation layer 703 and a second electrode layer (for example, a thin Ag film) 704 used as an upper electrode are formed on the first electrode layer 702.

The electricity generation layer 703 is a semiconductor film having a layer structure called a pin-junction in which an i-type amorphous silicon film 703i is interposed between a p-type silicon film 703p and an n-type silicon film 703n. Electrons and holes are generated in the amorphous silicon film 703i upon exposure to sunlight, which actively move by a potential difference between the p and n-type semiconductors. This mechanism occurs continuously and repeatedly, whereby a potential difference is created between the electrode layers 702 and 704 on both sides.

Here, if the amorphous silicon photovoltaic cell 700 has a structure in which the respective layers 702 to 704 are only uniformly formed over a large area of the glass substrate 701, the potential difference obtained with this structure is small, and a resistance is another problem. For this reason, for example, the laminated structure 705 is electrically partitioned into a predetermined size to form photovoltaic cells 706, and adjacent photovoltaic cells 706 are electrically connected.

Specifically, a scribe line 707 is formed on the laminated structure 705 uniformly formed over a large area of the glass substrate 701 using laser light or the like to obtain a plurality of strip-shaped photovoltaic cells 706. These photovoltaic cells 706 are electrically connected in series.

### CITATION LIST

### Non-Patent Document

[Non-Patent Document 1] “Let's Learn! Technical Description—New Energy—Photovoltaic Power Generation Related Projects”, [online], NEDO Technology Development Organization, [Searched on Jul. 6, 2010], Internet <URL: http://app2.infoc.nedo.go.jp/kaisetsu/neg/neg01/p01.html#elmtop>

However, since the respective photovoltaic cells 706 do not always provide desired output characteristics, if these photovoltaic cells 706 are only connected in series, there is a problem in that fluctuation in the output characteristics of individual products increases considerably.

### SUMMARY OF THE INVENTION

It is an aspect of the present application to provide a photovoltaic panel, a wristwatch, and a method of manufacturing the photovoltaic panel capable of suppressing fluctuation in the output characteristics of individual products.

According to another aspect of the application, there is provided a photovoltaic panel in which a plurality of photovoltaic cells is electrically connected in series, and in which at least one of the photovoltaic cells is set as a non-use cell depending on the output characteristics of the photovoltaic cell.

In the photovoltaic panel of the above aspect, the non-use cell may be not electrically connected to any of the other photovoltaic cells and may be not used.

In the photovoltaic panel of the above aspect, the non-use cell may be not used by shorting the electrodes of at least one of the photovoltaic cells or shorting the electrodes of at least two of the photovoltaic cells.

With this configuration, it is possible to adjust the output characteristics of a photovoltaic panel by changing the number of photovoltaic cells connected in series depending on the output characteristics of a photovoltaic cell. Thus, it is possible to suppress fluctuation in the output characteristics of the photovoltaic panel.

In the photovoltaic panel of the above aspect, the photovoltaic panel may further include a connection member that electrically connects the respective photovoltaic cells in series, and the connection member may be formed so as to connect the other photovoltaic cells excluding the at least one photovoltaic cell depending on the output characteristics of the photovoltaic cell.

With this configuration, it is possible to easily adjust the output characteristics of the photovoltaic panel and to improve the productivity of the photovoltaic panel.

In the photovoltaic panel of the above aspect, at least two of the photovoltaic cells may include: a first connection terminal for electrically connecting the adjacent photovoltaic cells; and a second connection terminal for electrically connecting the other photovoltaic cells which are not adjacent to each other.

With this configuration, it is possible to connect a plurality of photovoltaic cells without decreasing the light receiving area of the photovoltaic cell. Thus, it is possible to improve the output characteristics of the photovoltaic panel.

Moreover, since the photovoltaic cell includes the second connection terminal as well as the first connection terminal, it is possible to minimize the arrangement distance of the connection member for connecting photovoltaic cells on both sides of the non-use cell, for example. In this way, by enhancing the layout property of the connection member, it is possible to provide a photovoltaic panel with high output characteristics in a small space.

In the photovoltaic panel of the above aspect, the photovoltaic panel may further include a connection member that electrically connects the respective photovoltaic cells in series, and the connection member may be formed so as to short the electrodes of the at least one photovoltaic cell depending on the output characteristics of the photovoltaic cell.

With this configuration, it is possible to easily adjust the output characteristics of the photovoltaic panel and to improve the productivity of the photovoltaic panel.

In the photovoltaic panel of the above aspect, the at least one photovoltaic cell may include a short terminal for shorting the electrodes of the photovoltaic cell.

With this configuration, it is possible to easily short a photovoltaic cell so that the shorted photovoltaic cell can be used as a non-use cell that is not used.

According to another aspect of the application, there is provided a wristwatch in which the photovoltaic panel according to the above aspect is disposed on an outer surface of an outer casing thereof.

With this configuration, it is possible to provide a wristwatch in which fluctuation in the cell performance of products is small.

In the wristwatch of the above aspect, the photovoltaic cell disposed on a 9 o'clock side of the outer casing may be used as the non-use cell.

In general, in many cases, a wristwatch is worn on the left arm of a user. In such a case, the 9 o'clock side of the wristwatch may be covered by a sleeve. For example, when the photovoltaic cell is disposed at the position covered by the sleeve, sunlight is not likely to enter the photovoltaic cell, and the output characteristics may deteriorate. Thus, by disposing the non-use cell on the 9 o'clock side of the wristwatch, it is possible to suppress the cell characteristics of the wristwatch from being affected by a sleeve.

According to another aspect of the application, there is provided a method of manufacturing a photovoltaic panel including a plurality of photovoltaic cells, in which predetermined photovoltaic cells among the plurality of photovoltaic cells are electrically connected in series depending on the output characteristics of at least one of the photovoltaic cells.

According to another aspect of the application, there is provided a method of manufacturing a photovoltaic panel including a plurality of photovoltaic cells, in which at least two photovoltaic cells among the plurality of photovoltaic cells are shorted or the electrodes of a predetermined photovoltaic cell are shorted depending on the output characteristics of at least one of the photovoltaic cells.

With this method, it is possible to stabilize the output characteristics of the photovoltaic panel.

According to another aspect of the application, there is provided a method of manufacturing a photovoltaic panel, including: a step of setting a plurality of arrangement patterns of a connection member connecting a plurality of photovoltaic cells; a property examination step of examining the output characteristics of at least one of the photovoltaic cells; an arrangement pattern determining step of determining the arrangement pattern of the connection member based on an examination result in the property examination step; and an inter-cell connection step of connecting the plurality of photovoltaic cells using the connection member having the arrangement pattern determined in the arrangement pattern determining step.

With this configuration, it is possible to easily adjust the output characteristics of the photovoltaic panel and to improve the productivity of the photovoltaic panel.

According to the above aspects of the application, it is possible to adjust the output characteristics of a photovoltaic panel by changing the number of photovoltaic cells connected in series depending on the output characteristics of a photovoltaic cell. Thus, it is possible to suppress fluctuation in the output characteristics of the photovoltaic panel.

### BRIEF DESCRIPTION OF THE DRAWINGS

FIG. 1 is a plan view of a wristwatch according to a first embodiment of the invention.

FIG. 2 is a simplified and partially cross-sectional view of a photovoltaic panel according to a first embodiment of the invention.

FIGS. 3A to 3I are expanded plan views of the respective layers of the photovoltaic panel according to the first embodiment of the invention.

FIG. 4 is a flowchart showing a method of manufacturing the photovoltaic panel according to the first embodiment of the invention.

FIG. 5 is a graph showing fluctuation in the output voltage characteristics of the photovoltaic cells according to the first embodiment of the invention.

FIG. 6 is a plan view of a wristwatch according to a modified example of the invention.

FIG. 7 is a plan view of a wristwatch according to another modified example of the invention.

FIG. 8 is a plan view of a wristwatch according to another modified example of the invention.

FIG. 9 is a schematic cross-sectional view showing an example of an amorphous silicon photovoltaic cell according to the related art.

FIGS. 10A to 10I are expanded plan views of the respective layers of a photovoltaic panel according to a second embodiment of the invention.

### DETAILED DESCRIPTION OF THE INVENTION

### First Embodiment

### Wristwatch

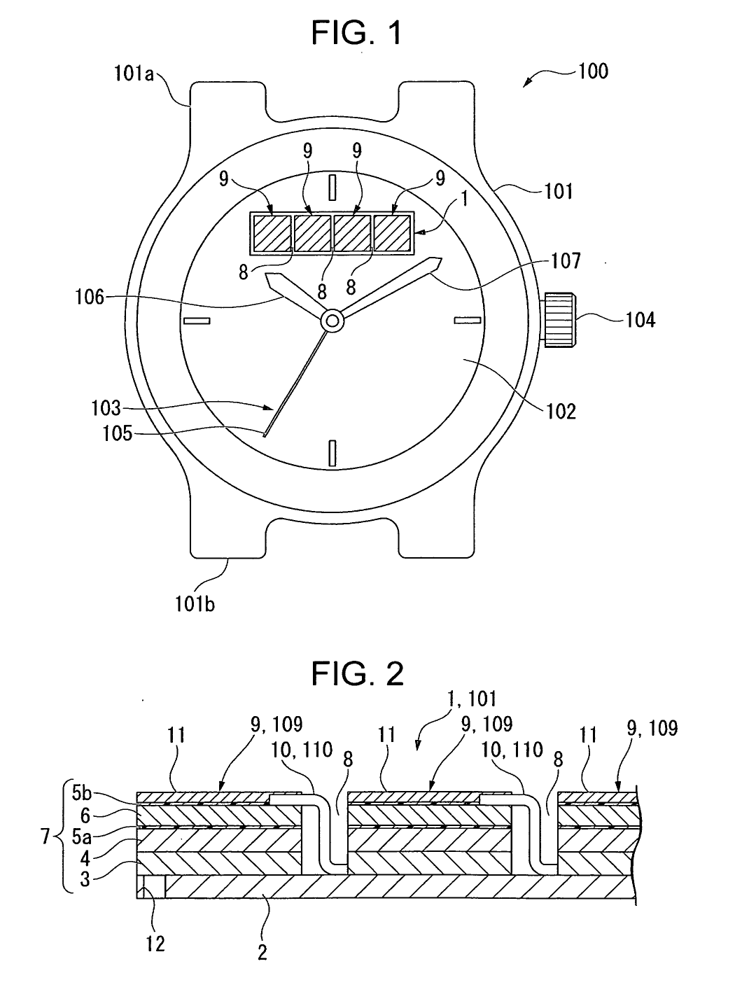

A first embodiment of the invention will be described with reference to FIGS. 1 to 8.

FIG. 1 is a plan view of a wristwatch having a photovoltaic panel according to the first embodiment of the invention.

As shown in the figure, a wristwatch 100 includes an outer casing 101, a second hand 105, a minute hand 106, and a hour hand 107 which is disposed on a character board 102 formed on the outer surface of the outer casing 101 and which forms a movement 103, and a photovoltaic panel 1 disposed on the character board 102.

Band attachment portions 101a and 101b to which a watchstrap (not shown) is attached are formed on the side surfaces of the outer casing 101 close to the 6 and 12 o'clock sides. Moreover, a winder 104 is formed on a side surface of the outer casing 101 close to the 3 o'clock side. Furthermore, the photovoltaic panel 1 is disposed on the 12 o'clock side of the character board 102.

(Photovoltaic Panel)

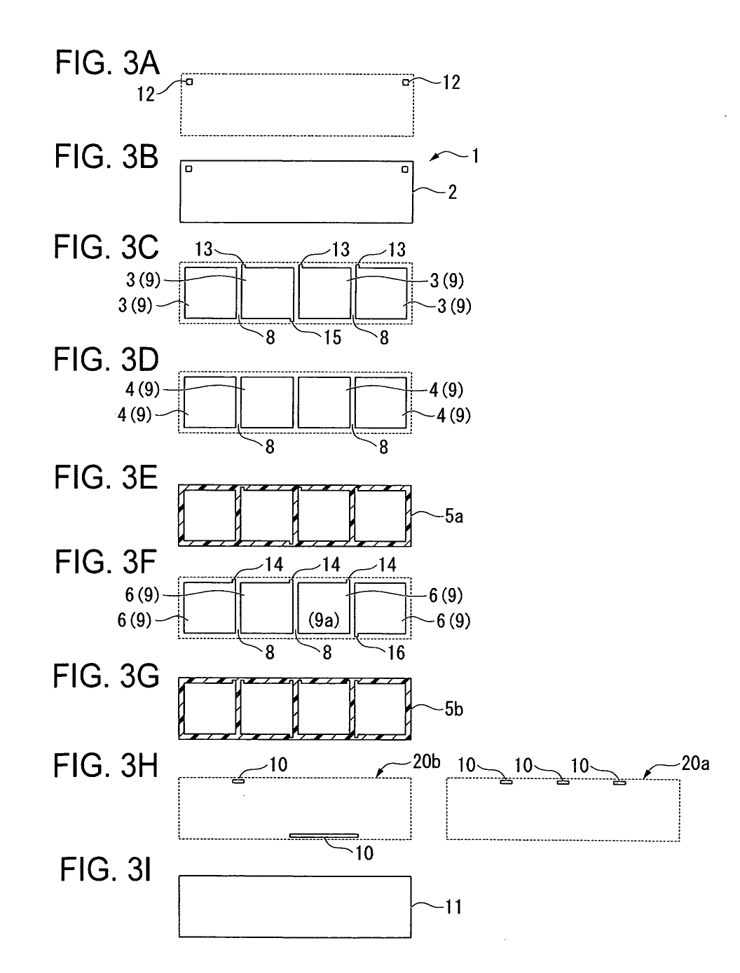

FIG. 2 is a simplified and partially cross-sectional view of a photovoltaic panel, and FIGS. 3A to 3I are expanded plan views of the respective layers of the photovoltaic panel.

As shown in FIGS. 1 to 3I, the photovoltaic panel 1 is a so-called amorphous silicon photovoltaic cell. That is, the photovoltaic panel 1 includes a laminated structure 7 which is formed by sequentially laminating a first electrode layer (lower electrode layer) 3, an electricity generation layer 4, an insulating layer 5, and a second electrode layer (upper electrode layer) 6 on one surface of a substrate 2. The laminated structure 7 is partitioned by a scribe line 8 to form a plurality of (for example, four in the first embodiment) photovoltaic cells 9, and these photovoltaic cells 9 are connected in series with an inter-cell electrode 10 disposed therebetween. Moreover, a protective layer 11 is formed on the second electrode layer 6.

As shown in FIGS. 2 and 3B, the substrate 2 is formed of an insulating material having excellent sunlight transmitting properties and durability, such as, for example, glass or a transparent resin.

As shown in FIGS. 2 and 3C, the first electrode layer 3 is formed of a transparent conductive material such as, for example, light transmitting metal oxides such as SnO₂, ITO, or ZnO.

As shown in FIGS. 2 and 3D, the electricity generation layer 4 has a pin junction structure, for example, in which an i-type amorphous silicon film is interposed between a p-type amorphous silicon film and an n-type amorphous silicon film (these films are not shown). Moreover, when sunlight enters the electricity generation layer 4, electrons and holes are generated, which actively move by a potential difference between the p-type amorphous silicon film and the n-type amorphous silicon film. This mechanism occurs continuously and repeatedly, whereby a potential difference is created between the first electrode layer 3 and the second electrode layer 6 (this is photoelectric conversion).

As shown in FIGS. 2 and 3F, the second electrode layer 6 is formed of a conductive light reflecting film such as, for example, Ag (silver) or Al (aluminum).

As shown in FIGS. 2, 3E, and 3G, insulating layers 5a and 5b are formed on both surfaces of the second electrode layer 6. These insulating layers 5a and 5b suppress diffusion and reaction of the second electrode layer 6 to and with silicon in the electricity generation layer 4. The insulating layers 5a and 5b are formed of ZnO, and the like, for example.

The laminated structure 7 formed in this way has a configuration, for example, in which the outer shape thereof is divided into four strip-shaped photovoltaic cells 9, and these photovoltaic cells 9 are arranged in a line. Moreover, the respective photovoltaic cells 9 are electrically connected in series with an inter-cell electrode 10 (see FIGS. 2 and 3H) disposed between the adjacent photovoltaic cells 9.

Furthermore, a terminal electrode 12 disposed on the substrate 2 is connected to the two photovoltaic cells 9 disposed on the outermost sides (see FIGS. 2 and 3A). In this way, the photovoltaic panel 1 can extract current with a high potential difference.

Here, as shown in FIGS. 3C and 3F, a first connection terminal 13 for connecting the adjacent photovoltaic cells 9 is formed on one side of the first electrode layer 3 so as to protrude in the plane direction of the first electrode layer 3. Moreover, a first connection terminal 14 for connecting the adjacent photovoltaic cells 9 is formed on one side of the second electrode layer 6 so as to protrude in the plane direction of the second electrode layer 6. These first connection terminals 13 and 14 are connected by the inter-cell electrode 10.

A second connection terminal 15 is formed on the other side of a predetermined first electrode layer 3 among the four first electrode layers 3, namely in the first embodiment, the first electrode layer 3 disposed at the second place from the left in FIG. 3C so as to protrude in the plane direction of the first electrode layer 3. Moreover, a second connection terminal 16 is formed on the other side of a predetermined second electrode layer 6 among the four second electrode layers 6, namely in the first embodiment, the second electrode layer 6 disposed on the rightmost side in FIG. 3F so as to protrude in the plane direction of the second electrode layer 6.

These second connection terminals 15 and 16 are used when connecting three photovoltaic cells 9 in series rather than connecting all four of the photovoltaic cells 9 in series.

Here, in the photovoltaic panel 1, the output voltage characteristics of an optional photovoltaic cell 9 are examined in the course of the manufacturing process, and it is determined whether three or four photovoltaic cells 9 will be connected in series based on the examination result. When three photovoltaic cells 9 are connected in series, the second connection terminals 15 and 16 formed on the respective electrode layers 3 and 6 are used.

(Method of Manufacturing Photovoltaic Panel)

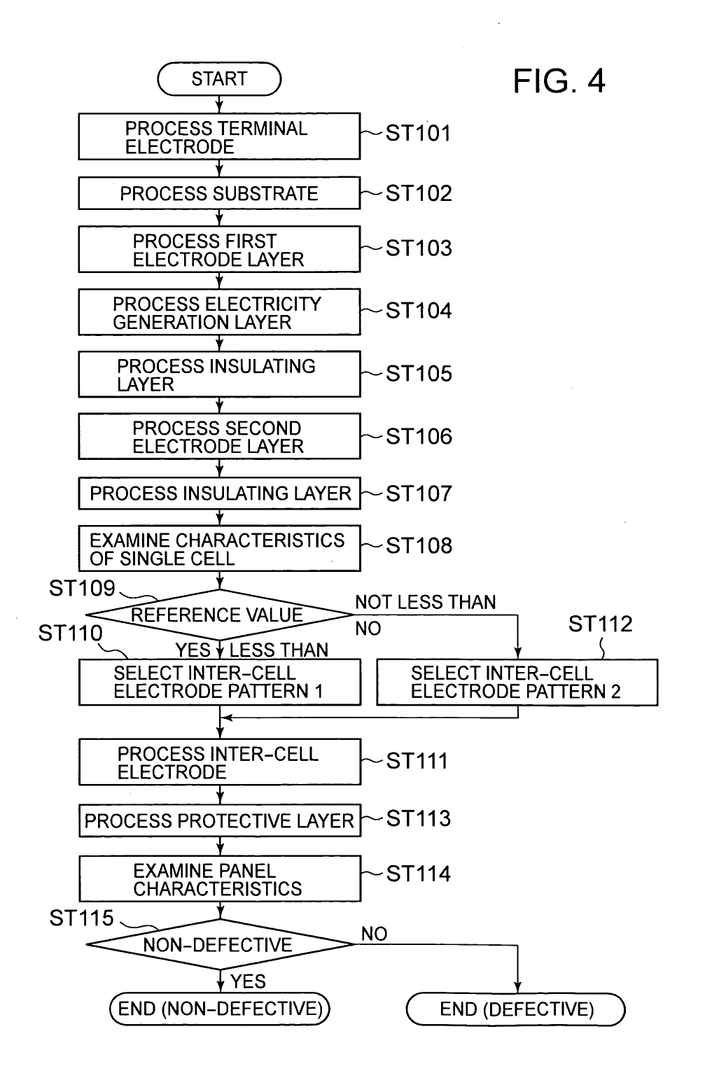

A method of manufacturing the photovoltaic panel 1 will be described in more detail with reference to FIGS. 3A to 4.

FIG. 4 is a flowchart showing a method of manufacturing a photovoltaic panel.

As shown in FIG. 4, when manufacturing the photovoltaic panel 1, first, the terminal electrode 12 for extracting electricity generated by the photovoltaic panel 1 is processed (ST101).

Subsequently, the substrate 2 is processed (ST102). Subsequently, the substrate 2 is cleaned, and the substrate 2 is loaded into a thermal CVD (Chemical Vapor Deposition) machine, for example. In the thermal CVD machine, the first electrode layer 3 is formed on the substrate 2 (ST103).

Subsequently, a p-type amorphous silicon film, an i-type amorphous silicon film, and an n-type amorphous silicon film are formed in that order on the first electrode layer 3 using a plasma CVD machine, for example. In this way, the electricity generation layer 4 is formed on the first electrode layer 3 (see ST104).

Subsequently, the insulating layer 5a, the second electrode layer 6, and the insulating layer 5b are formed in that order on the electricity generation layer 4 using a sputtering machine, for example (ST105, ST106, and ST107).

Through such a method, the laminated structure 7 is formed. Moreover, the laminated structure 7 is partitioned into a strip shape along scribe lines 8 by laser light, for example, whereby a plurality of (four in the first embodiment) photovoltaic cells 9 is formed (see FIGS. 3A to 3I).

Subsequently, as shown in FIG. 4, the output voltage characteristics of one optional photovoltaic cell 9 are examined (ST108: property examination step). As the examination method, for example, a method may be used in which first, in a state where the probe of a voltage detection device (not shown) is attached between the first electrode layer 3 and the second electrode layer 6 of an optional photovoltaic cell 9, the photovoltaic cell 9 is directly irradiated with light, and the output voltage value is detected.

Subsequently, it is determined whether the output voltage value obtained by the examination in ST108 is less than a reference value (ST109).

In the first embodiment, a desired output voltage value of one photovoltaic cell 9 is 0.6 V, for example, and the desired output voltage value (0.6 V) is set as the reference value. Moreover, based on the determination in ST109, the pattern of the inter-cell electrode 10 described later is selected, and the number of photovoltaic cells 9 connected in series is determined (arrangement pattern determining step).

That is, as shown in FIG. 3H, the inter-cell electrode 10 electrically connecting the photovoltaic cells 9 includes two patterns 20a and 20b, in which the first pattern 20a connects only the first connection terminals 13 and 14, and the second pattern 20b connects only the second connection terminals 15 and 16.

When the first pattern 20a is used, the four photovoltaic cells 9 are connected in series. On the other hand, when the second pattern 20b is used, three photovoltaic cells 9 are connected in series.

More specifically, the inter-cell electrodes 10 of the first pattern 20a are arranged at three positions so as to bridge over the first connection terminals 13 and 14 which are formed in the adjacent photovoltaic cells 9 and 9. In this way, when the first pattern 20a is used, the four photovoltaic cells 9 are connected in series by the inter-cell electrodes 10.

On the other hand, the inter-cell electrodes 10 of the second pattern 20b are arranged so as to bridge across the first connection terminals 13 and 14 which are formed in the first and second photovoltaic cells 9 and 9 from the left side in FIGS. 3C and 3F and are also arranged so as to bridge across the second connection terminals 15 and 16 which are formed in the second and fourth photovoltaic cells 9 and 9 from the left side in the figures.

That is, the second photovoltaic cell 9 from the left is connected to a photovoltaic cell 9 located next to the photovoltaic cell 9 on the right side of the second photovoltaic cell 9. Thus, the third photovoltaic cell 9 from the left is set as a non-use cell 9a which is connected to none of the other photovoltaic cells 9. With this configuration, when the second pattern 20b is used, three photovoltaic cells 9 are connected in series by the inter-cell electrodes 10.

In this way, the respective photovoltaic cells 9 are connected by the inter-cell electrodes 10 which are arranged so as to bridge over the first connection terminals 13 and 14 and the second connection terminals 15 and 16 which are formed in the respective photovoltaic cells 9. Thus, the inter-cell electrodes 10 are not arranged on the respective electrode layers 3 and 6 of the photovoltaic cells 9, and thus, a reduction in the light receiving area can be prevented.

As shown in FIG. 4, when the determination in ST109 results in “Yes,” namely the output voltage characteristics of one optional photovoltaic cell 9 is less than a reference value (in the first embodiment, 0.6 V), the first pattern 20a of the inter-cell electrode 10 is selected (ST110). Moreover, the inter-cell electrode 10 is processed based on the first pattern 20a (ST111), and four photovoltaic cells 9 are connected in series (inter-cell connection step).

On the other hand, when the determination in ST109 is “No,” namely the output voltage characteristics of one optional photovoltaic cell 9 is not less than the reference value, the second pattern 20b of the inter-cell electrode 10 is selected (ST112). Moreover, the inter-cell electrode 10 is processed based on the second pattern 20b (ST111), and three photovoltaic cells 9 are connected in series (inter-cell connection step).

That is, when the output voltage value of the photovoltaic cell 9 is less than a desired value, all photovoltaic cells 9 are used so as to obtain a desired output voltage value as the whole photovoltaic panel 1. On the other hand, when the output voltage value of the photovoltaic cell 9 is not less than a desired value, the number of photovoltaic cells 9 connected is decreased so as to obtain a desired output voltage value as the whole photovoltaic panel 1.

After electrically connecting the respective photovoltaic cells 9 by the inter-cell electrodes 10, the protective layer 11 is formed on the second electrode layer 6 and the inter-cell electrodes 10 using a sputtering machine, for example (ST113).

Subsequently, the output voltage characteristics of the photovoltaic panel 1 are examined (ST114). Based on the examination result, whether the photovoltaic panel 1 outputs a desired voltage value and can be judged as a non-defective product is determined (ST115). Moreover, non-defective products and defective products are classified, and the manufacturing of the photovoltaic panel 1 ends.

As the examination method, for example, a method may be used in which first, in a state where the probe of a voltage detection device (not shown) is attached between two terminal electrodes 12, the photovoltaic panel 1 is directly irradiated with light, and the output voltage value is detected.

(Effects)

According to the first embodiment described above, the output voltage characteristics of one optional photovoltaic cell 9 are examined (property examination step). The number of photovoltaic cells 9 to be connected in series is adjusted by selecting one of the patterns 20a and 20b of the inter-cell electrode 10 in accordance with the examination result (arrangement pattern determining step). Then, the photovoltaic cells 9 are connected in series (inter-cell connection step). Thus, it is possible to suppress fluctuation in the output voltage characteristics of the photovoltaic panel 1.

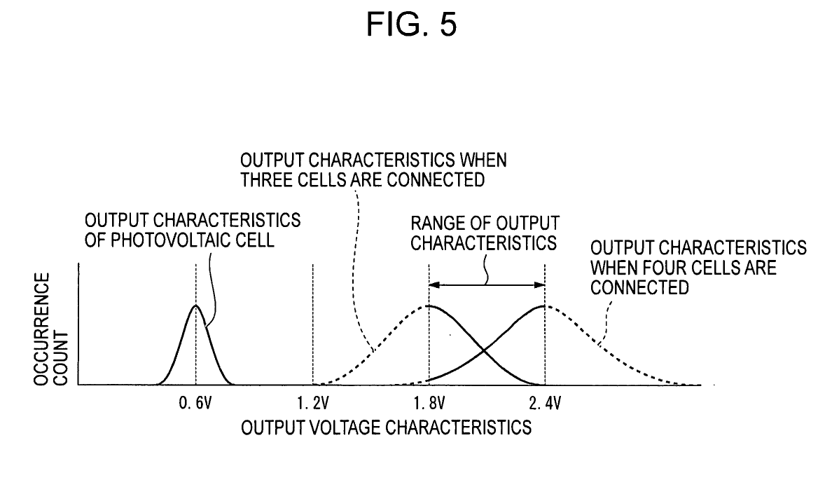

The effects of the photovoltaic panel 1 will be described in more detail with reference to FIG. 5.

FIG. 5 is a graph showing fluctuation of output voltage characteristics of a photovoltaic cell, in which the vertical axis represents the number of photovoltaic cells (occurrence count), and the horizontal axis represents the output voltage characteristics.

As shown in the figure, when the desired output voltage value (reference value) is 0.6 V, the output voltage characteristics of the photovoltaic cell 9 fluctuate with a peak around 0.6 V.

Here, when the examination result shows that the output voltage characteristics of the photovoltaic cell 9 is not less than 0.6V, since the photovoltaic panel 1 is manufactured using the inter-cell electrode 10 of the second pattern 20b, three photovoltaic cells 9 among the four photovoltaic cells 9 are connected in series. On the other hand, when the output voltage characteristics of the photovoltaic cell 9 is less than 0.6 V, since the photovoltaic panel 1 is manufactured using the inter-cell electrode 10 of the first pattern 20a, all four of the photovoltaic cells 9 are connected in series. In this way, by adjusting the number of photovoltaic cells 9, the output voltage characteristics of the photovoltaic cell 9 can be set to fall within the range of 1.8 V to 2.4 V.

Moreover, the respective photovoltaic cells 9 are connected using the inter-cell electrode 10, and the two first and second patterns 20a and 20b are used as the arrangement pattern of the inter-cell electrode 10 (see FIG. 3H). Thus, it is possible to easily adjust the output voltage characteristics of the photovoltaic panel 1 and improve the productivity of the photovoltaic panel 1.

Furthermore, the first connection terminals 13 or the first connection terminals 14 are formed so as to protrude from the respective photovoltaic cells 9, and the second connection terminals 15 or the second connection terminals 16 are formed so as to protrude from a predetermined photovoltaic cell 9. Thus, since the inter-cell electrode 10 is not arranged on the respective electrode layers 3 and 6 of the photovoltaic cell 9, and a reduction in the light receiving area can be prevented, it is possible to improve the output voltage characteristics of the photovoltaic panel 1.

Moreover, since the second connection terminals 15 and 16 are formed so as to protrude, it is possible to connect the photovoltaic cells 9 and 9 at both sides of the non-use cell 9a with the shortest distance. That is, it is not necessary to arrange the inter-cell electrodes 10 so as to avoid the non-use cell 9a along a detour path, and the arrangement distance of the inter-cell electrodes 10 can be minimized. In this way, by enhancing the layout property of the inter-cell electrodes 10, it is possible to provide the photovoltaic panel 1 with high output voltage characteristics in a small space.

Furthermore, by arranging the photovoltaic panel 1 within the outer casing 101, it is possible to provide the wristwatch 100 with small fluctuation in cell performance.

In the first embodiment, a case where the photovoltaic panel 1 is disposed on the 12 o'clock side of the character board 102 of the wristwatch 100 has been described. However, the position and shape of the photovoltaic panel 1 is not limited to those of the first embodiment.

### Modified Example

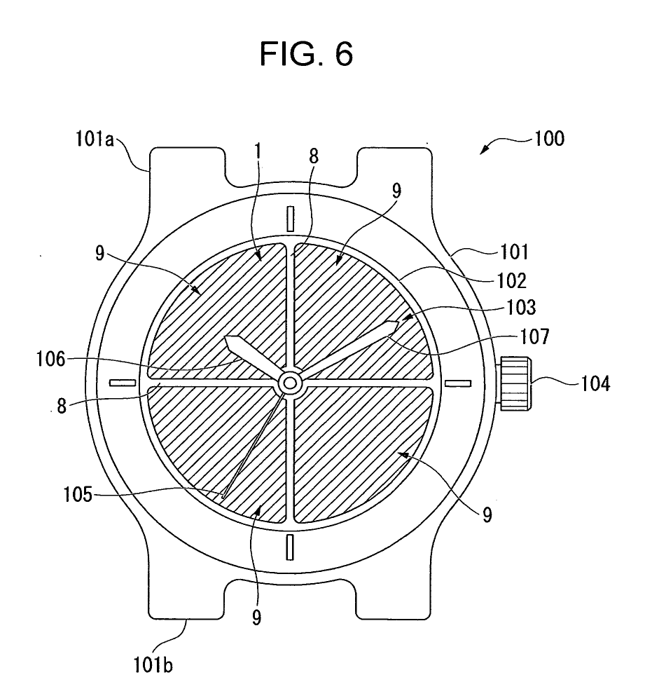

Hereinafter, modified examples of the photovoltaic panel arranged in the wristwatch 100 will be described with reference to FIGS. 6 to 8.

FIGS. 6 to 8 are plan views of a wristwatch. In regard to the configuration of a wristwatch, the same configurations as those of the first embodiment will be denoted by the same reference numerals, and redundant description thereof is not provided (the same is applied to the embodiment described later).

As shown in FIG. 6, the photovoltaic panel 1 may be arranged on the entire character board 102 of the wristwatch 100. In this case, scribe lines 8 may be formed along the direction from 12 o'clock to 6 o'clock and the direction from 3 o'clock to 9 o'clock, and four photovoltaic cells 9 may be arranged clockwise. With this configuration, it is possible to increase the light receiving area of the photovoltaic panel and to provide the wristwatch 100 having higher cell efficiency.

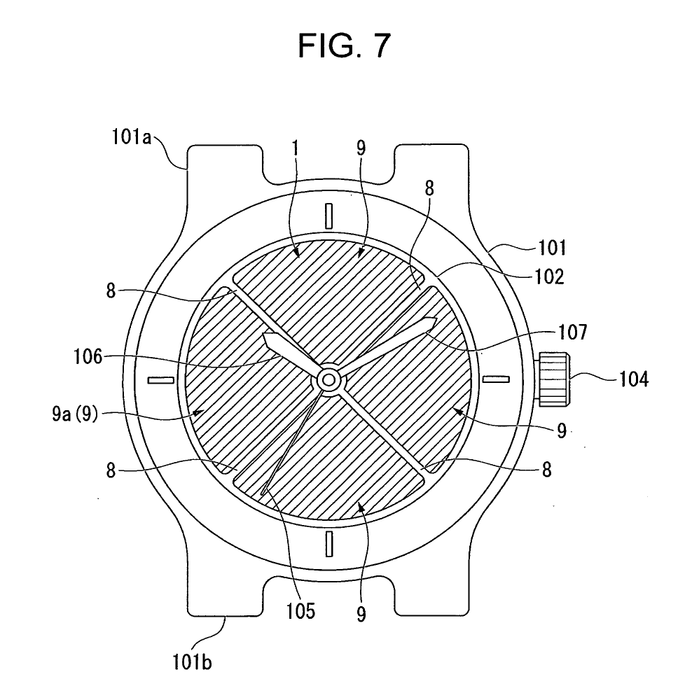

Moreover, as shown in FIG. 7, four photovoltaic cells 9 may be arranged so that the respective photovoltaic cells are located at the 12, 3, 6, and 9 o'clock sides.

Here, when arranging the four photovoltaic cells 9 as shown in the figure, it is preferable to set the photovoltaic cell 9 on the 9 o'clock side as the non-use cell 9a. That is, in general, in many cases, since the wristwatch 100 is worn on the left arm of a user, in such a case, the 9 o'clock side of the wristwatch 100 may be covered by a sleeve (not shown). Thus, by setting the photovoltaic cell 9 on the 9 o'clock side as the non-use cell 9a, it is possible to suppress the cell characteristics of the wristwatch 100 from being affected by a sleeve (not shown).

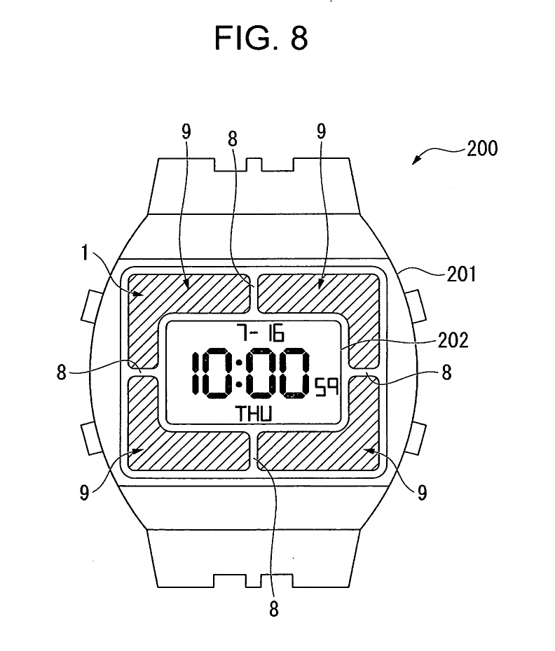

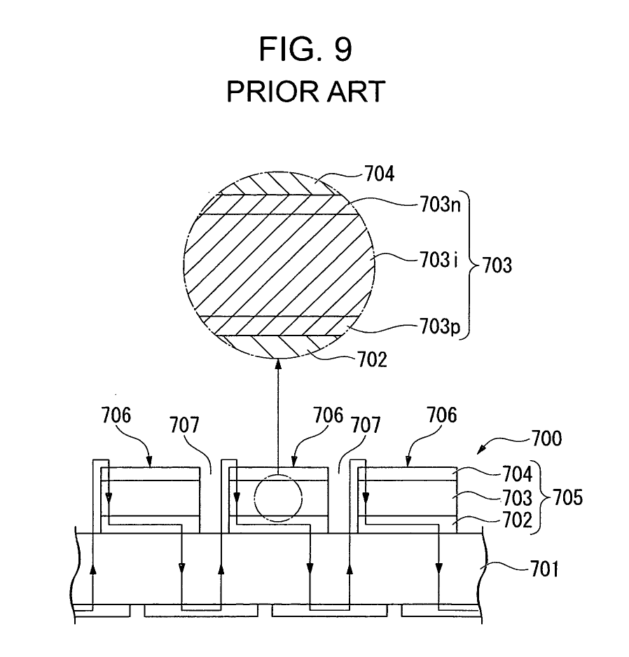

Furthermore, as shown in FIG. 8, in the case of a digital wristwatch 200, the photovoltaic panel 1 may be arranged on the outer surface of an outer casing 201 so as to surround a liquid crystal panel 202 for displaying time and the like.

In addition, the inter-cell electrodes 10 that connect the photovoltaic cells 9 arranged as shown in FIGS. 6 to 8 are preferably arranged on the scribe line 8 or around the photovoltaic cells 9.

### Second Embodiment

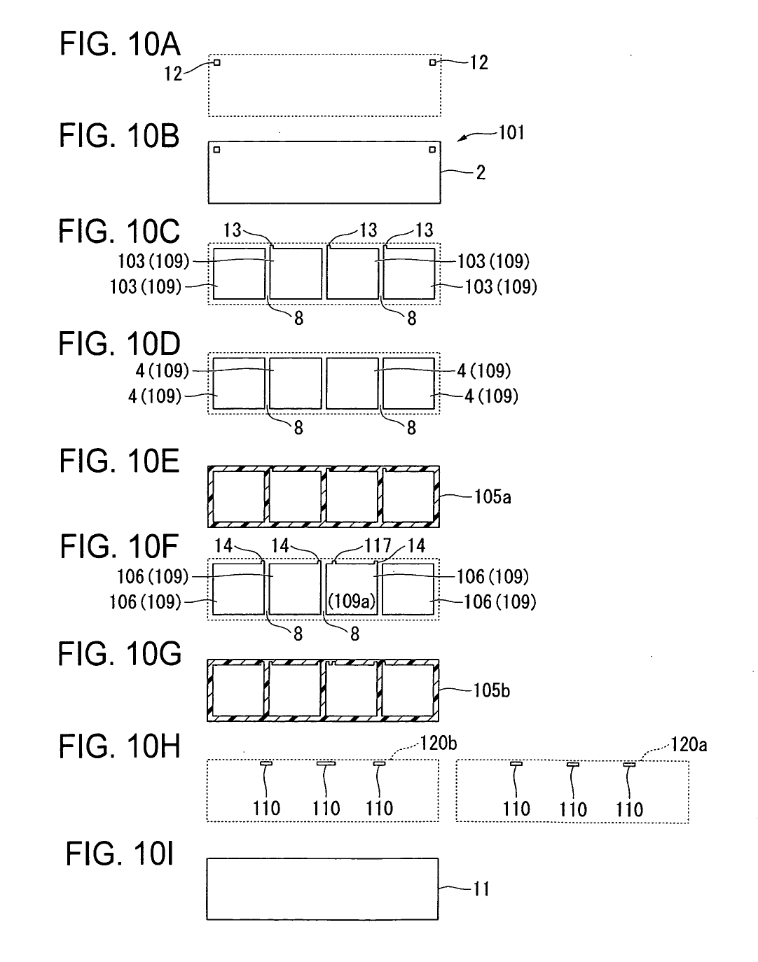

Next, a second embodiment of the invention will be described with reference to FIG. 2 and FIGS. 10A to 10I.

FIGS. 10A to 10I are expanded plan views of the respective layers of a photovoltaic panel according to a second embodiment of the invention.

In the second embodiment, a photovoltaic panel 101 is a so-called amorphous silicon photovoltaic cell and has substantially the same configuration as the first embodiment described above. That is, the photovoltaic panel 101 includes a laminated structure 7 which is formed by sequentially laminating a first electrode layer (lower electrode layer) 3, an electricity generation layer 4, an insulating layer 5, and a second electrode layer (upper electrode layer) 6 on one surface of a substrate 2. The laminated structure 7 is partitioned by a scribe line 8 to form a plurality of photovoltaic cells 109, and these photovoltaic cells 109 are connected in series by an inter-cell electrode 110 disposed therebetween.

Here, in the photovoltaic panel 101, the output voltage characteristics of an optional photovoltaic cell 109 are examined in the course of the manufacturing process, and it is determined whether three or four photovoltaic cells 109 will be connected in series based on the examination result. When connecting three photovoltaic cells 109 in series, the connection structure in the second embodiment is different from the connection structure in the first embodiment. This difference will be described in detail.

As shown in FIGS. 10C and 10F, the second connection terminals 15 and 16 (see FIGS. 3C and 3F) which are used when connecting three photovoltaic cells 109 in series are not formed on the first and second electrode layers 103 and 106 of the second embodiment. Moreover, instead of the second connection terminal 16, a short terminal 117 is formed on one side (the upper side in FIG. 10F) of a predetermined second electrode layer 106 among the four second electrode layers 106, namely in the second embodiment, the second electrode layer 106 disposed at the third place from the left in FIG. 10F so as to protrude in the plane direction of the second electrode layer 106.

The short terminal 117 is connected to the first connection terminal 13 of the first electrode layer 103 of the photovoltaic cell 109 where the short terminal 117 is formed through an inter-cell electrode 110 (see FIG. 10H).

Moreover, as shown in FIGS. 3E and 3G, insulating layers 105a and 105b disposed on both sides of the second electrode layer 106 are formed so as to correspond to the first and second electrode layers 103 and 106.

Here, the inter-cell electrode 110 includes two patterns 120a and 120b, in which the first and second patterns 120a and 120b connect only the first connection terminals 13 and 14. The first pattern 120a is configured to so that the four photovoltaic cells 9 are connected in series.

On the other hand, the second pattern 120b is configured so as to connect the short terminal 117 and the first connection terminals 13 which are formed on the first electrode layer 103 corresponding to the second electrode layer 106 where the short terminal 117 is formed. That is, the inter-cell electrode 110 at the center of the second pattern 120b is formed so as to connect the first connection terminal 14 formed on the second photovoltaic cell 109 from the left in FIGS. 10C and 10F, the first connection terminal 13 formed on the third photovoltaic cell 109 from the left, and the short terminal 117. Thus, when the second pattern 120b is used, the four photovoltaic cells 9 are connected in series. However, in this case, since a photovoltaic cell 109 where the short terminal 117 is formed among these photovoltaic cells has the first electrode layer 103 and the second electrode layer 106 which are shorted, the photovoltaic cell 109 is set as a non-use cell 109a.

In such a configuration, the output voltage characteristics of one optional photovoltaic cell 109 are examined, and when the output voltage value is less than a reference value, the first pattern 120a of the inter-cell electrode 110 is selected. Moreover, the four photovoltaic cells 109 are connected in series.

On the other hand, when the output voltage characteristics of one optional photovoltaic cell 109 is not less than the reference value, the second pattern 120b of the inter-cell electrode 110 is selected. In this way, only three photovoltaic cells 109 are used.

Therefore, according to the second embodiment described above, it is possible to obtain the same effects as the first embodiment described above.

In the second embodiment above, a configuration in which the inter-cell electrodes 110 of the second pattern 120b are configured to connect the short terminal 117 and the first connection terminal 13 which is formed on the first electrode layer 103 corresponding to the second electrode layer 106 where the short terminal 117 is formed has been described. However, the invention is not limited to this, and the inter-cell electrodes 110 of the second pattern 120b may be configured to connect the short terminal 117 and the first connection terminal 14 of the second electrode layer 106 of the photovoltaic cell 109 adjacent to the photovoltaic cell 109 where the short terminal 117 is formed. With this configuration, it is also possible to the third photovoltaic cell 109 from the left in FIG. 10F as the non-use cell 109a.

Moreover, the invention is not limited to the embodiments described above, but various changes can be made in the above-described embodiments within a range without departing from the spirit of the invention.

For example, in the embodiments described above, a case where the voltage value is detected as a method of examining the output characteristics of the photovoltaic cell 9 has been described. However, the examination method is not limited to this, and any method capable of checking the output characteristics of the photovoltaic cell 9 can be used. For example, a current value may be detected instead of the voltage value.

Furthermore, in the embodiments described above, a case where the photovoltaic panel 1 includes four photovoltaic cells 9 has been described. However, the invention is not limited to this, and the photovoltaic panel 1 may include two or more plural photovoltaic cells 9.

Furthermore, in the embodiments described above, a case where, when connecting three photovoltaic cells 9 or 109 among the four photovoltaic cells 9 or 109 in series, the third photovoltaic cell 9 or 109 from the left in FIGS. 3F and 10F is set as the non-use cell 9a or 109a has been described. However, the invention is not limited to this, and an optional photovoltaic cell 9 or 109 may be set as the non-use cell 9a or 109a. Moreover, the invention is not limited to a case where one photovoltaic cell is set as the non-use cell 9a or 109a, but two or more photovoltaic cells may be set as the non-used cells.

Moreover, the arrangement pattern of the inter-cell electrodes 10 or 110 may be changed depending on the position of the non-use cell 9a or 109a. Furthermore, the invention is not limited to a case where the inter-cell electrodes 10 or 110 have two patterns 20a and 20b or 120a and 120b, three or more patterns may be prepared as necessary.

Moreover, a case where, when examining the output voltage characteristics of the photovoltaic cell 9 or 109, only one optional photovoltaic cell 9 or 109 is examined, and the inter-cell electrodes 10 or 110 of the first pattern 20a or 120a or the inter-cell electrodes 10 or 110 of the second pattern 20b or 120b are selected based on the examination result has been described. However, the invention is not limited to this, and the output voltage characteristics of all photovoltaic cells 9 or 109 may be examined, and the connection pattern of the photovoltaic cells 9 or 109 may be determined based on the examination result.

What is claimed is:

1. A photovoltaic panel in which a plurality of photovoltaic cells is electrically connected in series,
wherein at least one of the photovoltaic cells is set as a non-use cell depending on the output characteristics of the photovoltaic cell.

2. The photovoltaic panel according to claim 1,
wherein the non-use cell is not electrically connected to any of the other photovoltaic cells and is not used.

3. The photovoltaic panel according to claim 2, further comprising a connection member that electrically connects the respective photovoltaic cells in series,
wherein the connection member is formed so as to connect the other photovoltaic cells excluding the at least one photovoltaic cell depending on the output characteristics of the photovoltaic cell.

4. The photovoltaic panel according to claim 1,
wherein at least two of the photovoltaic cells includes:
a first connection terminal for electrically connecting adjacent photovoltaic cells; and
a second connection terminal for electrically connecting the other photovoltaic cells which are not adjacent to each other.

5. The photovoltaic panel according to claim 2,
wherein at least two of the photovoltaic cells includes:
a first connection terminal for electrically connecting adjacent photovoltaic cells; and
a second connection terminal for electrically connecting the other photovoltaic cells which are not adjacent to each other.

6. The photovoltaic panel according to claim 3,
wherein at least two of the photovoltaic cells includes:
a first connection terminal for electrically connecting adjacent photovoltaic cells; and
a second connection terminal for electrically connecting the other photovoltaic cells which are not adjacent to each other.

7. The photovoltaic panel according to claim 1,
wherein the non-use cell is not used by shorting the electrodes of one of the photovoltaic cells or shorting at least two of the photovoltaic cells.

8. The photovoltaic panel according to claim 7, further comprising a connection member that electrically connects the respective photovoltaic cells in series,
wherein the connection member is formed so as to short the electrodes of the at least one photovoltaic cell depending on the output characteristics of the photovoltaic cell.

9. The photovoltaic panel according to claim 1, wherein the at least one photovoltaic cell includes a short terminal for shorting the electrodes of the photovoltaic cell.

10. The photovoltaic panel according to claim 7, wherein the at least one photovoltaic cell includes a short terminal for shorting the electrodes of the photovoltaic cell.

11. The photovoltaic panel according to claim 8, wherein the at least one photovoltaic cell includes a short terminal for shorting the electrodes of the photovoltaic cell.

12. A wristwatch in which the photovoltaic panel according to claim 1 is disposed on an outer surface of an outer casing thereof.

13. A wristwatch in which the photovoltaic panel according to claim 2 is disposed on an outer surface of an outer casing thereof.

14. A wristwatch in which the photovoltaic panel according to claim 3 is disposed on an outer surface of an outer casing thereof.

15. A wristwatch in which the photovoltaic panel according to claim 4 is disposed on an outer surface of an outer casing thereof.

16. A wristwatch in which the photovoltaic panel according to claim 5 is disposed on an outer surface of an outer casing thereof.

17. The wristwatch according to claim 12, wherein the photovoltaic cell disposed on a 9 o'clock side of the outer casing is set as the non-use cell.

18. A method of manufacturing a photovoltaic panel including a plurality of photovoltaic cells,
wherein predetermined photovoltaic cells among the plurality of photovoltaic cells are electrically connected in series depending on the output characteristics of at least one of the photovoltaic cells.

19. A method of manufacturing a photovoltaic panel including a plurality of photovoltaic cells,
wherein at least two photovoltaic cells among the plurality of photovoltaic cells are shorted or the electrodes of a predetermined photovoltaic cell are shorted depending on the output characteristics of at least one of the photovoltaic cells.

20. A method of manufacturing a photovoltaic panel, comprising:
a step of setting a plurality of arrangement patterns of a connection member connecting a plurality of photovoltaic cells;
a property examination step of examining the output characteristics of at least one of the photovoltaic cells;
an arrangement pattern determining step of determining the arrangement pattern of the connection member based on an examination result in the property examination step; and
an inter-cell connection step of connecting the plurality of photovoltaic cells using the connection member having the arrangement pattern determined in the arrangement pattern determining step.
